(19) United States
(12) Patent Application Publication
(10) Pub. No.: US 2026/0321307 A1
(43) Pub. Date: Oct. 15, 2026

(54) MEMORY DEVICE AND OPERATING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Ching-Wang YAO, New Taipei City (TW); Yu-Sheng LAI, Taichung City (TW); Tao CHOU, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 19/178,227

(22) Filed: Apr. 14, 2025

(51) Int. Cl. G11C 11/4096; G11C 11/408; G11C 11/4093

(52) U.S. Cl. CPC G11C 11/4096; G11C 11/4085; G11C 11/4093

(57) ABSTRACT

A memory device, the memory comprises a write circuit configured to write a stored bit into a storage node, when a first control signal has a first voltage level. The memory comprises a storage circuit configured to store the stored bit at the storage node and receive the first control signal. Wherein when the first control signal has a second voltage level, the storage circuit computes the stored bit with an input bit to generate an output bit, and the second voltage level is higher than the first voltage level.

### BACKGROUND

A memory device is configured to store bits of the input data and perform a logic computation to the store bits. When performing the logic computation, some stored bits are refreshed in each computing period. A polarization of the memory device must be set prior to the logic computation in each computing period to prevent the stored bits from being refreshed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device, illustrated in accordance with some embodiments of the present disclosure.

FIG. 2 is a timing diagram of signals of the memory device, illustrated in accordance with some embodiments of the present disclosure.

FIG. 3A is a table of logic values, corresponding to the logic computation of the memory device, illustrated in accordance with some embodiments of the present disclosure.

FIG. 3B is a table of logic values, corresponding to the logic computation of the memory device, illustrated in accordance with some embodiments of the present disclosure.

FIG. 3C is a table of logic values, corresponding to the logic computation of the memory device, illustrated in accordance with some embodiments of the present disclosure.

FIG. 4A is a timing diagram of voltage signals in FIG. 3A, illustrated in accordance with some embodiments of the present disclosure.

FIG. 4B is a timing diagram of voltage signals in FIG. 3A, illustrated in accordance with some embodiments of the present disclosure.

FIG. 5A is a timing diagram of voltage signals in FIG. 3B, illustrated in accordance with some embodiments of the present disclosure.

FIG. 5B is a timing diagram of voltage signals in FIG. 3B, illustrated in accordance with some embodiments of the present disclosure.

FIG. 6A is a timing diagram of voltage signals in FIG. 3C, illustrated in accordance with some embodiments of the present disclosure.

FIG. 6B is a timing diagram of voltage signals in FIG. 3C, illustrated in accordance with some embodiments of the present disclosure.

FIG. 7 is a cross section diagram of the memory device, illustrated in accordance with some embodiments of the present disclosure.

FIG. 8 is a schematic diagram of a system for designing and manufacturing at least one of the memory devices described herein, illustrated in accordance with some embodiments of the present disclosure.

FIG. 9 is a block diagram of an integrated circuit (IC)/semiconductor system manufacturing system, and an IC manufacturing flow associated therewith, illustrated in accordance with some embodiments of the present disclosure.

FIG. 10 is a flow diagram of a method of operating the memory device illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

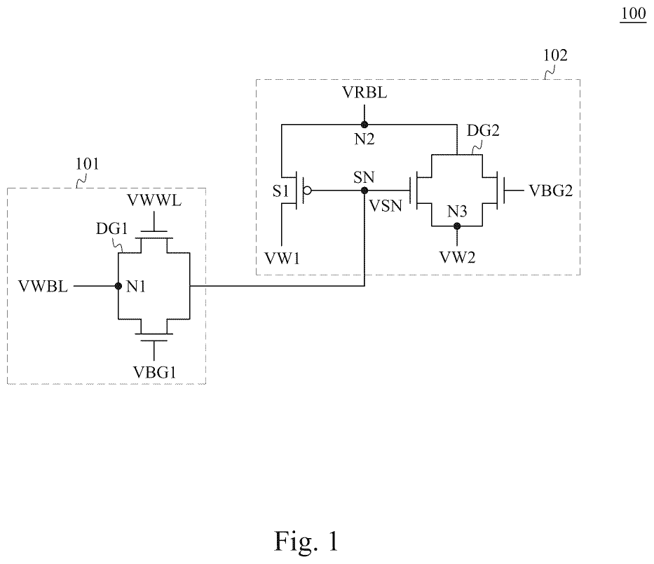

FIG. 1 is a schematic diagram of a memory device 100, illustrated in accordance with some embodiments of the present disclosure. As illustratively shown in FIG. 1, the memory device 100 includes a write circuit 101 and a storage circuit 102. The write circuit 101 includes a switch DG1. The storage circuit 102 includes switches DG1 and S1.

In some embodiments, the write circuit 101 is configured to write a stored bit SBT1 into the storage circuit 102. The storage circuit 102 is configured to compute the stored bit SBT1 with an input bit INB1 to generate an output bit OUTB1.

Specifically, the write bit line signal VWBL is configured to carry the stored bit SBT1. The write circuit 101 is configured to transmit the write bit line signal VWBL into the storage circuit 102 to adjust a storage node signal VSN at a storage node SN in the storage circuit 102. In some embodiments, the storage circuit 102 is configured to store the stored bit SBT1 at the storage node SN and perform a logic computation to the stored bit SBT1 and the input bit INB1 according to the control signal VBG2 to generate a read bit line signal VRBL. The read bit line signal VRBL is configured to carry the output bit OUTB1.

As illustratively shown in FIG. 1, a terminal of the switch DG1 is configured to receive a write bit line voltage VWBL at a node N1. Another terminal of the switch DG1 is coupled to each of a control terminal of the switch DG1 and a control terminal of the switch S1 at the storage node SN. A control terminal of the switch DG1 is configured to receive the write word line signal VWWL. A gate terminal of the switch DG1 is configured to receive a control signal VBG1.

In some embodiments, a terminal of the switch DG2 is coupled to a terminal of the switch S1 at a node N2. Another terminal of the switch DG2 is configured to receive a voltage signal VW2 at a node N3. A gate terminal of the switch DG2 is configured to receive a control signal VBG2. A terminal of the switch S1 is configured to output the read bit line signal VRBL at the node N2. Another terminal of the switch S1 is configured to receive a voltage signal VW1.

In some embodiments, each of the switches DG1 and DG2 is implemented by a Dual-gate Oxide Semiconductor Field-Effect Transistor (OSFET).

In some embodiments, the memory device 100 is implemented by dynamic random-access memory (DRAM), static random-access memory (SRAM) or other type of memory in practical application.

In some embodiments, each of the switches DG1 and DG2 is implemented by a transistor of a first conductive type, such as an N-type transistor. When a control terminal of the transistor of the first conductive type has the voltage level V2, the transistor is turned on. When a control terminal of the transistor of the first conductive type has the voltage level V0, the transistor is turned off.

In some embodiments, the switch S1 is implemented by a transistor of a second conductive type, such as a P-type transistor. When a control terminal of the transistor of the second conductive type has the voltage level V1, the transistor is turned on. When a control terminal of the transistor of the second conductive type has the voltage level V2, the transistor is turned off. In some embodiments, the voltage level V2 is higher than the voltage level V0.

In some embodiments, the control terminal of the switch DG1 has a threshold voltage VDGT1. The control signal VBG1 is configured to adjust a voltage level of the threshold voltage VDGT1 during different operations. Specifically, during a write operation, the control signal VBG1 is configured to provide a positive bias to adjust the threshold voltage VDGT1 to a voltage level VT_L. At this moment, the write word line signal VWWL has a voltage level V2 such that the switch DG1 is turned on. In response to the switch DG1 being turned on, the write circuit 101 transmits the write bit line signal VWBL to the storage node SN. In response to the control signal VBG1 providing the positive bias, the control signal VBG1 has a voltage level VP.

In some embodiments, during a read operation, the control signal VBG1 is configured to provide a negative bias to adjust the threshold voltage VDGT1 to a voltage level VT_H. In response to the control signal VBG1 providing the negative bias, the control signal VBG1 has a voltage level VN. At this moment, the write word line signal VWWL has a voltage level V0 such that the switch DG1 is turned off. In response to the switch DG1 being turned on, the write circuit 101 receives the write bit line signal VWBL. In response to the control signal VBG1 providing the positive bias, the control signal VBG1 has a voltage level VP.

In some embodiments, the voltage level VT_H is higher than the voltage level VT_L. In some embodiments, adjusting the threshold voltage VDGT1 to a higher voltage level by the negative bias is configured to prevent a leakage current flowing between the storage node SN and the node N2.

In some embodiments, when the threshold voltage VDGT1 is increased, a turn on voltage level of the write word line signal VWWL is higher. For example, when the threshold voltage VDGT1 is increased, each of the voltage levels V1 and V2 is increased.

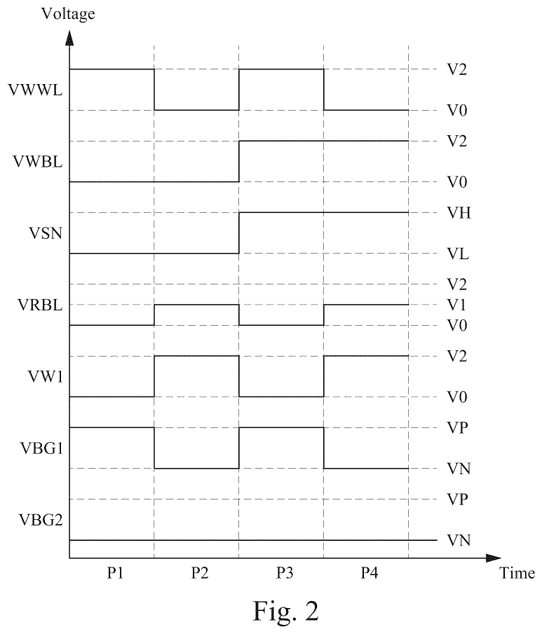

In some embodiments, when the control signal VBG2 has the voltage level VN, the storage circuit 102 stores the stored bit SBT1 at the storage node SN. When the control signal VBG2 has the voltage level VP, the storage circuit 102 performs the logic computation according to the storage node signal VSN, the voltage signals VW1 and VW2. Alternatively, after the stored bit SBT1 is stored into the storage node SN by the storage circuit 102, the control signal VBG1 has the voltage level VN. Further details regarding the operation of the memory device 100 is discussed in FIG. 2 to FIG. 6B and corresponding paragraph of the presented disclosure.

In some embodiments, the threshold voltage VDGT1 of the switch DG1 and a threshold voltage VDGT2 of the switch DG2 are adjusted by the control signals VBG1 and VBG2, respectively. When the control signals VBG1 and VBG2 provide the positive bias to the switches DG1 and DG2, the threshold voltages VDGT1 and VDGT2 are shifted from a positive level to a negative level, respectively. For example, each of the threshold voltages VDGT1 and VDGT2 shifts from 0.75 volt to −0.75 volt. When the control signals VBG1 and VBG2 provide the negative bias to the switches DG1 and DG2, the threshold voltages VDGT1 and VDGT2 are shifted from the negative level to the positive level, respectively. For example, each of the threshold voltages VDGT1 and VDGT2 shifts from −0.75 volt to 0.75 volt.

In some embodiments, when the control signal VBG2 has the voltage level VN, the memory device 100 is operated as a memory gain cell. In some embodiments, when the control signal VBG2 has the voltage level VP, the storage circuit 102 is configured to perform a Compute-In-Memory (CIM) operation. The CIM operation includes logic operations, such as OR operation, AND operation, and XOR operation.

In some approach, when a memory device performs a logic computation, some stored bits are refreshed in each computing period. In some other approach, a polarization of the memory device must be set prior to the logic computation, such that the stored bits are not refreshed in each computing period.

Compared to above approaches, in some embodiments of present disclosure, the memory device 100 operates as the memory gain cell, when the control signal VBG2 provides the negative bias corresponding to the voltage level VN. Relatively, the storage circuit 102 of the memory device 100 performs the logic computation, when the control signal VBG2 provides the positive bias corresponding to the voltage level VP. Accordingly, the storage circuit 102 stores the stored bit SBT1 and performs the logic computation according to the control signal VBG2. As a result, the stored bit SBT1 is not refreshed in each computing period, when the memory device 100 performs the logic computation.

FIG. 2 is a timing diagram of signals of the memory device 100, illustrated in accordance with some embodiments of the present disclosure. Referring to FIG. 2 and FIG. 1, FIG. 2 shows the variation of the write word line signal VWWL, the write bit line signal VWBL, the storage node signal VSN, the read word line signal VW1, the read bit line signal VRBL, and the control signals VBG1 and VBG2 in FIG. 1 during the periods P1-P4. As illustratively shown in FIG. 2, during the periods P1-P4 the control signal VBG2 is maintained at the voltage level VN. Accordingly, the memory device 100 operates as the memory gain cell during the periods P1-P4.

In some embodiments, when the stored bit SBT1 has a logic value “0”, the write bit line signal VWBL has the voltage level V0. During the periods P1-P4, the voltage signal VW2 is maintained at a ground voltage level GND.

During the period P1, the memory device 100 performs the write operation to write the stored bit SBT1 having the logic value “0” into the storage node SN. The control signal VBG1 has the voltage level VP, to provide the positive bias.

At this moment, the write word line signal VWWL has the voltage level V2, such that the switch DG1 is turned on. In response to the switch DG1 being turned on, the switch DG1 transmits the write bit line signal VWBL to the storage node SN, such that the storage node signal VSN has the voltage level VL and the stored bit SBT1 having the logic value “0” is stored into the storage node SN.

During the period P2, the memory device 100 performs the read operation to read the stored bit SBT1 having the logic value “0” from the storage node SN. The control signal VBG1 has the voltage level VN, to provide the negative bias.

At this moment, the write word line signal VWWL has the voltage level V2, such that the switch DG1 is turned off. The read bit line signal VRBL changes from the voltage level V0 to the voltage level V2. The read word line signal VW1 changes from the voltage level V0 to the voltage level V2, such that the stored bit SBT1 having the logic value “0” is transmitted to the node N2.

During the period P3, the memory device 100 performs the write operation to write the stored bit SBT1 having the logic value “1” into the storage node SN. The control signal VBG1 has the voltage level VP, to provide the positive bias.

At this moment, the write word line signal VWWL has the voltage level V2, such that the switch DG1 is turned on. In response to the switch DG1 being turned on, the switch DG1 transmits the write bit line signal VWBL to the storage node SN, such that the storage node signal VSN has the voltage level VL and the stored bit SBT1 having the logic value “1” is stored into the storage node SN.

During the period P4, the memory device 100 performs the read operation to read the stored bit SBT1 having the logic value “1” from the storage node SN. The control signal VBG1 has the voltage level VN, to provide the negative bias.

At this moment, the write word line signal VWWL has the voltage level V2, such that the switch DG1 is turned off. The voltage level of the read bit line signal VRBL switches from the voltage level V0 to the voltage level V2, configured to read the stored bit SBT1. The voltage level of the read word line signal VW1 switches from the voltage level V0 to the voltage level V2, such that the stored bit SBT1 having the logic value “1” is transmitted to the node N2.

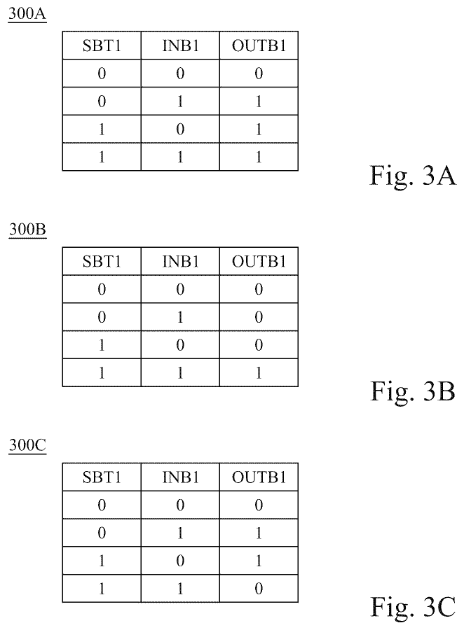

FIG. 3A is a table 300A of logic values, corresponding to the logic computation of the memory device 100, illustrated in accordance with some embodiments of the present disclosure. In some embodiments, the logic computation of the table 300A corresponds to an OR operation.

Referring to FIG. 3A and FIG. 1, in the condition shown in the table 300A, the control signals VBG1 and VBG2 has the voltage levels VN and VP, respectively. In response to the control signal VBG2 having the voltage level VP, the storage circuit 102 performs the OR operation. In the OR operation, the storage circuit 102 receives the voltage signal VW1 carrying the input bit INB1 and computes the input bit INB1 with the stored bit SBT1 to generate the read bit line signal VRBL at the node N2. The read bit line signal VRBL carries the output bit OUTB1. The voltage signal VW2 has a voltage level VDD. In some embodiments, the voltage level VDD is higher than the ground voltage level GND, and corresponds to the logic value “1”.

In some embodiments, when the storage node signal VSN has the voltage level VL, the stored bit SBT1 having the logic value “0” is stored into the storage node SN. In response to the storage node signal VSN having the voltage level VL, the switch S1 is turned on, and the switch DG2 is turned off. In response to the switch S1 being turned on, the input bit INB1 is transmitted to the node N2 to generate the read bit line signal VRBL. Accordingly, the voltage level of the read bit line signal VRBL is same as the voltage level of the voltage signal VW1. When the input bit INB1 has the logic value “0”, the output bit OUTB1 has the logic value “0”. On the other hand, when the input bit INB1 has the logic value “1”, the output bit OUTB1 has the logic value “1”.

In some embodiments, when the storage node signal VSN has the voltage level VH, the stored bit SBT1 having the logic value “1” is stored into the storage node SN. In response to the storage node signal VSN having the voltage level VH, the switch S1 is turned off, and the switch DG2 is turned on. In response to the switch DG2 being turned on, the reference voltage VDD is transmitted to the node N2 to generate the read bit line signal VRBL, such that the output bit OUTB1 has the logic value “1”.

At this moment, the input bit INB1 is terminated in response to the switch S1 is turned off. Accordingly, the output bit OUTB1 has the voltage value “1” when the input bit INB1 has either the logic value “1” or the logic value “0”.

FIG. 3B is a table 300B of logic values, corresponding to the logic computation of the memory device 100, illustrated in accordance with some embodiments of the present disclosure. In some embodiments, the logic computation of the table 300B corresponds to an AND operation.

Referring to FIG. 3B and FIG. 1, in the condition shown in the table 300B, the control signals VBG1 and VBG2 has the voltage levels VN and VP, respectively. In response to the control signal VBG2 having the voltage level VP, the storage circuit 102 performs the AND operation. In the AND operation, the storage circuit 102 receives the voltage signal VW2 carrying the input bit INB1 and computes the input bit INB1 with the stored bit SBT1 to generate the read bit line signal VRBL at the node N2. The read bit line signal VRBL carries the output bit OUTB1. The voltage signal VW1 has the ground voltage level GND. In some embodiments, the ground voltage level GND corresponds to the logic value “0”.

In some embodiments, when the storage node signal VSN has the voltage level VL, the stored bit SBT1 having the logic value “0” is stored into the storage node SN. In response to the storage node signal VSN having the voltage level VL, the switch S1 is turned on, and the switch DG2 is turned off. In response to the switch S1 being turned on, the voltage signal VW1 having the logic value “0” is transmitted to the node N2 to generate the read bit line signal VRBL. Accordingly, the voltage level of the read bit line signal VRBL is same as the voltage level of the voltage signal VW1.

At this moment, the input bit INB1 is terminated in response to the switch DG2 is turned off. Accordingly, the output bit OUTB1 has the voltage value “0” when the input bit INB1 has either the logic value “1” or the logic value “0”.

In some embodiments, when the storage node signal VSN has the voltage level VH, the stored bit SBT1 having the logic value “1” is stored into the storage node SN. In response to the storage node signal VSN having the voltage level VH, the switch S1 is turned off, and the switch DG2 is turned on. In response to the switch DG2 being turned on, the voltage signal VW2 is transmitted to the node N2 to generate the read bit line signal VRBL. The voltage level of the read bit line signal VRBL is same as the voltage level of the voltage signal VW2. Accordingly, when the input bit INB1 has the logic value “0”, the output bit OUTB1 has the logic value “0”. On the other hand, when the input bit INB1 has the logic value “1”, the output bit OUTB1 has the logic value “1”.

FIG. 3C is a table 300C of logic values, corresponding to the logic computation of the memory device 100, illustrated in accordance with some embodiments of the present disclosure. In some embodiments, the logic computation of the table 300C corresponds to an XOR operation.

Referring to FIG. 3C and FIG. 1, in the condition shown in the table 300C, the control signals VBG1 and VBG2 has the voltage levels VN and VP, respectively. In response to the control signal VBG2 having the voltage level VP, the storage circuit 102 performs the XOR operation. In the XOR operation, the storage circuit 102 receives the voltage signals VW1 and VW2 carrying the input bit INB1 and an input bit INB1B. The storage circuit 102 computes the input bits INB1 and INB1B with the stored bit SBT1 to generate the read bit line signal VRBL at the node N2. The read bit line signal VRBL carries the output bit OUTB1. In some embodiments, the input bit INB1B is complementary to the input bit INB1. For example, when the input bit INB1 has the logic value “1”, the input bit INB1B has the logic value “0”. When the input bit INB1 has the logic value “0”, the input bit INB1B has the logic value “1”.

In some embodiments, when the storage node signal VSN has the voltage level VL, the stored bit SBT1 having the logic value “0” is stored into the storage node SN. In response to the storage node signal VSN having the voltage level VL, the switch S1 is turned on, and the switch DG2 is turned off. In response to the switch S1 being turned on, the input bit INB1 is transmitted to the node N2 to generate the read bit line signal VRBL. The voltage level of the read bit line signal VRBL is same as the voltage level of the voltage signal VW1. Accordingly, when the input bit INB1 has the logic value “0”, the output bit OUTB1 has the logic value “0”. On the other hand, when the input bit INB1 has the logic value “1”, the output bit OUTB1 has the logic value “1”.

In some embodiments, when the storage node signal VSN has the voltage level VH, the stored bit SBT1 having the logic value “1” is stored into the storage node SN. In response to the storage node signal VSN having the voltage level VH, the switch S1 is turned off, and the switch DG2 is turned on. In response to the switch DG2 being turned on, the input bit INB1B is transmitted to the node N2 to generate the read bit line signal VRBL. Accordingly, when the input bit INB1 has the logic value “1”, the output bit OUTB1 has the voltage value “0”. On the other hand, when the input bit INB1 has the logic value “0”, the output bit OUTB1 has the voltage value “1”.

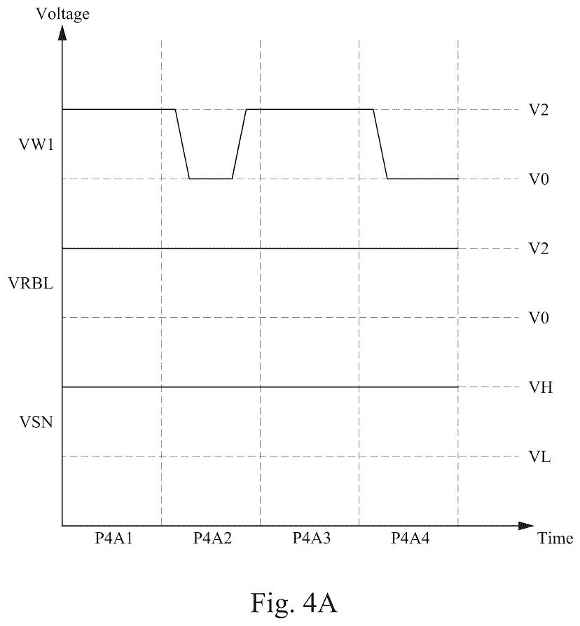

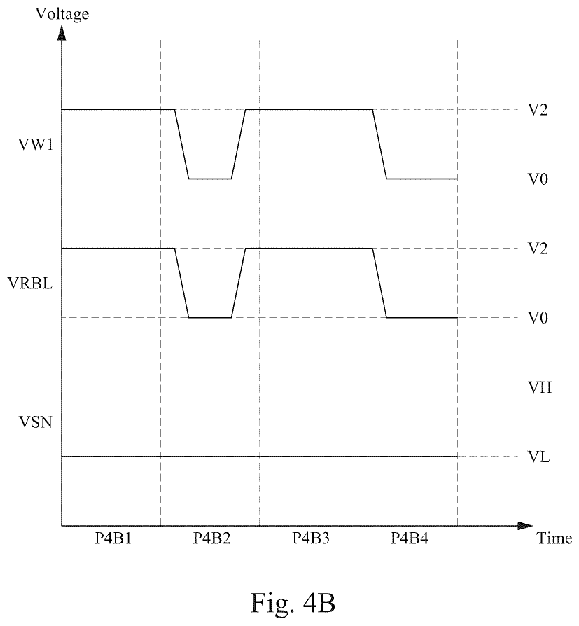

FIG. 4A is a timing diagram of voltage signals in FIG. 3A, illustrated in accordance with some embodiments of the present disclosure. Referring to FIG. 4A, FIG. 3A, and FIG. 1, FIG. 4A illustrates the variations of the voltage signals VW1, the read bit line signal VRBL, and the storage node signal VSN during periods P4A1-P4A4. In some embodiments, FIG. 4A corresponds to the stored bit SBT1 having the logic value “1” in FIG. 3A.

During the period P4A1, the stored bit SBT1 has the logic value “1”, such that the storage node signal VSN has the voltage level VH. The input bit INB1 has the logic value “1”, such that the voltage signal VW1 has the voltage level V2. In response to the stored bit SBT1 having the logic value “1” and the input bit INB1 having the logic value “1”, the read bit line signal VRBL has the voltage level V2 corresponding to the logic value “1”.

During the period P4A2, the storage node signal VSN has the voltage level VH, corresponding to the stored bit SBT1 having the logic value “1”. The input bit INB1 has the logic value “0”, such that the voltage signal VW1 has the voltage level V0. In response to the stored bit SBT1 having the logic value “1” and the input bit INB1 having the logic value “0”, the read bit line signal VRBL has the voltage level V2 corresponding to the logic value “1”.

During the period P4A3, the storage node signal VSN has the voltage level VH, corresponding to the stored bit SBT1 having the logic value “1”. The input bit INB1 has the logic value “1”, such that the voltage signal VW1 has the voltage level V2. In response to the stored bit SBT1 having the logic value “1” and the input bit INB1 having the logic value “1”, the read bit line signal VRBL has the voltage level V2 corresponding to the logic value “1”.

During the period P4A4, the storage node signal VSN has the voltage level VH, corresponding to the stored bit SBT1 having the logic value “1”. The input bit INB1 has the logic value “0”, such that the voltage signal VW1 has the voltage level V0. In response to the stored bit SBT1 having the logic value “1” and the input bit INB1 having the logic value “0”, the read bit line signal VRBL has the voltage level V2 corresponding to the logic value “1”.

FIG. 4B is a timing diagram of voltage signals in FIG. 3A, illustrated in accordance with some embodiments of the present disclosure. Referring to FIG. 4B, FIG. 3A, and FIG. 1, FIG. 4B illustrates the variations of the voltage signals VW1, the read bit line signal VRBL, and the storage node signal VSN during periods P4B1-P4B4. In some embodiments, FIG. 4B corresponds to the stored bit SBT1 having the logic value “0” in FIG. 3A.

During the period P4B1, the stored bit SBT1 has the logic value “0”, such that the storage node signal VSN has the voltage level VL. The input bit INB1 has the logic value “1”, such that the voltage signal VW1 has the voltage level V2. In response to the stored bit SBT1 having the logic value “0” and the input bit INB1 having the logic value “1”, the read bit line signal VRBL has the voltage level V2 corresponding to the logic value “1”.

During the period P4B2, the storage node signal VSN has the voltage level VL, corresponding to the stored bit SBT1 having the logic value “0”. The input bit INB1 has the logic value “0”, such that the voltage signal VW1 has the voltage level V0. In response to the stored bit SBT1 having the logic value “0” and the input bit INB1 having the logic value “0”, the read bit line signal VRBL has the voltage level V0 corresponding to the logic value “0”.

During the period P4B3, the storage node signal VSN has the voltage level VL, corresponding to the stored bit SBT1 having the logic value “0”. The input bit INB1 has the logic value “1”, such that the voltage signal VW1 has the voltage level V2. In response to the stored bit SBT1 having the logic value “0” and the input bit INB1 having the logic value “1”, the read bit line signal VRBL has the voltage level V2 corresponding to the logic value “1”.

During the period P4B4, the storage node signal VSN has the voltage level VL, corresponding to the stored bit SBT1 having the logic value “0”. The input bit INB1 has the logic value “0”, such that the voltage signal VW1 has the voltage level V0. In response to the stored bit SBT1 having the logic value “0” and the input bit INB1 having the logic value “0”, the read bit line signal VRBL has the voltage level V2 corresponding to the logic value “0”.

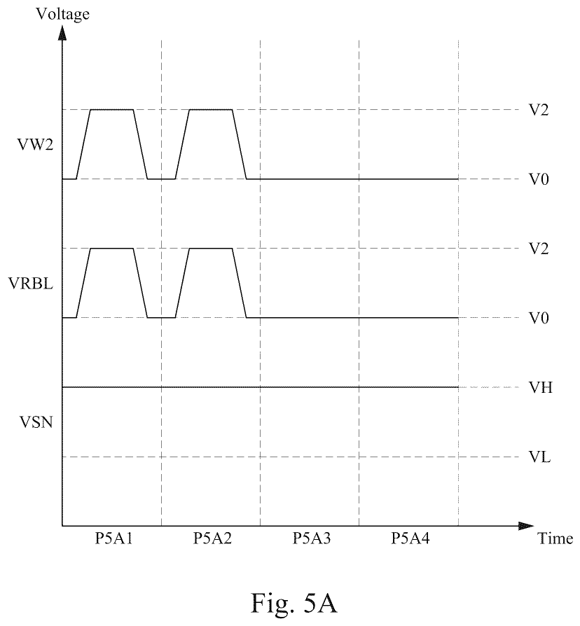

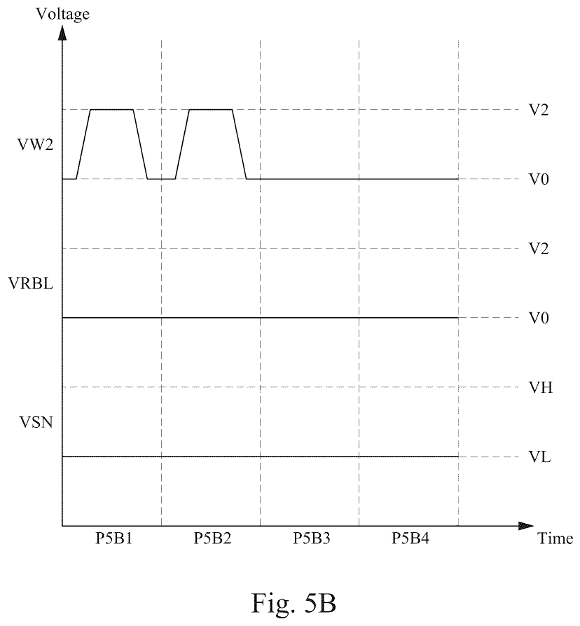

FIG. 5A is a timing diagram of voltage signals in FIG. 3B, illustrated in accordance with some embodiments of the present disclosure. Referring to FIG. 5A, FIG. 3B, and FIG. 1, FIG. 5A illustrates the variations of the voltage signals VW2, the read bit line signal VRBL, and the storage node signal VSN during periods P5A1-P5A4. In some embodiments, FIG. 5A corresponds to the stored bit SBT1 having the logic value “1” in FIG. 3B.

During the period P5A1, the stored bit SBT1 has the logic value “1”, such that the storage node signal VSN has the voltage level VH. The input bit INB1 has the logic value “1”, such that the voltage signal VW2 has the voltage level V2. In response to the stored bit SBT1 having the logic value “1” and the input bit INB1 having the logic value “1”, the read bit line signal VRBL has the voltage level V2 corresponding to the logic value “1”.

During the period P5A2, similar to the period P5A1, the storage node signal VSN has the voltage level VH, and the voltage signal VW2 has the voltage level V2, such that the read bit line signal VRBL has the voltage level V2 corresponding to the logic value “1”.

During the period P5A3, the storage node signal VSN has the voltage level VH, corresponding to the stored bit SBT1 having the logic value “1”. The input bit INB1 has the logic value “0”, such that the voltage signal VW2 has the voltage level V0. In response to the stored bit SBT1 having the logic value “1” and the input bit INB1 having the logic value “0”, the read bit line signal VRBL has the voltage level V0 corresponding to the logic value “0”.

During the period P5A4, similar to the period P5A3, the storage node signal VSN has the voltage level VH, and the voltage signal VW2 has the voltage level V0, such that the read bit line signal VRBL has the voltage level V0 corresponding to the logic value “0”.

FIG. 5B is a timing diagram of voltage signals in FIG. 3B, illustrated in accordance with some embodiments of the present disclosure. Referring to FIG. 5B, FIG. 3B, and FIG. 1, FIG. 5B illustrates the variations of the voltage signals VW2, the read bit line signal VRBL, and the storage node signal VSN during periods P5B1-P5B4. In some embodiments, FIG. 5B corresponds to the stored bit SBT1 having the logic value “0” in FIG. 3B.

During the period P5B1, the stored bit SBT1 has the logic value “0”, such that the storage node signal VSN has the voltage level VL. The input bit INB1 has the logic value “1”, such that the voltage signal VW2 has the voltage level V2. In response to the stored bit SBT1 having the logic value “0” and the input bit INB1 having the logic value “1”, the read bit line signal VRBL has the voltage level V0 corresponding to the logic value “0”.

During the period P5B2, similar to the period P5B1, the storage node signal VSN has the voltage level VL, and the voltage signal VW2 has the voltage level V2, such that the read bit line signal VRBL has the voltage level V0 corresponding to the logic value “0”.

During the period P5B3, the storage node signal VSN has the voltage level VL, corresponding to the stored bit SBT1 having the logic value “0”. The input bit INB1 has the logic value “0”, such that the voltage signal VW2 has the voltage level V0. In response to the stored bit SBT1 having the logic value “0” and the input bit INB1 having the logic value “0”, the read bit line signal VRBL has the voltage level V0 corresponding to the logic value “0”.

During the period P5B4, similar to the period P5B3, the storage node signal VSN has the voltage level VL, and the voltage signal VW2 has the voltage level V0, such that the read bit line signal VRBL has the voltage level V0 corresponding to the logic value “0”.

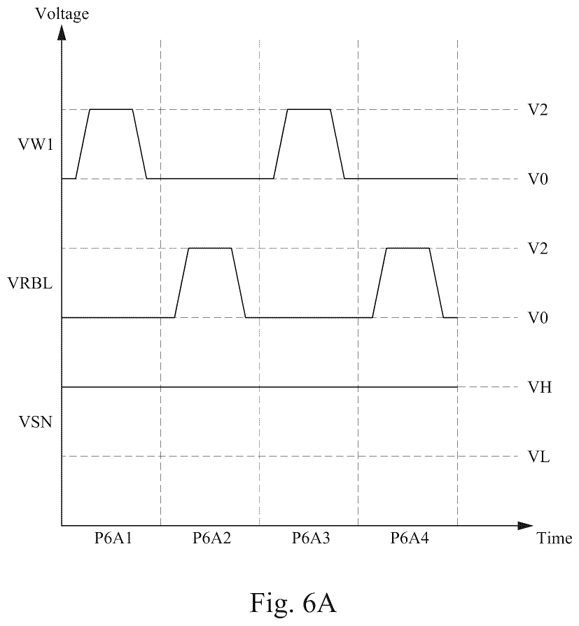

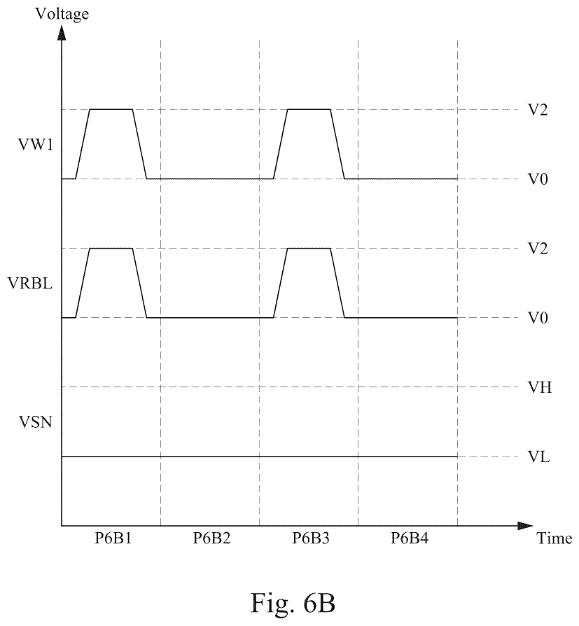

FIG. 6A is a timing diagram of voltage signals in FIG. 3C, illustrated in accordance with some embodiments of the present disclosure. Referring to FIG. 6A, FIG. 3C, and FIG. 1, FIG. 6A illustrates the variations of the voltage signals VW1, the read bit line signal VRBL, and the storage node signal VSN during periods P6A1-P6A4. In some embodiments, FIG. 6A corresponds to the stored bit SBT1 having the logic value “1” in FIG. 3C.

During the period P6A1, the stored bit SBT1 has the logic value “1”, such that the storage node signal VSN has the voltage level VH. The input bit INB1 has the logic value “1”, such that the voltage signal VW1 has the voltage level V2. In response to the input bit INB1 having the logic value “1”, the input bit INB1B has the logic value “0”. In response to the stored bit SBT1 having the logic value “1” and the input bit INB1B having the logic value “0”, the read bit line signal VRBL has the voltage level V0 corresponding to the logic value “0”.

During the period P6A2, the storage node signal VSN has the voltage level VH, corresponding to the stored bit SBT1 having the logic value “1”. The input bit INB1 has the logic value “0”, such that the voltage signal VW1 has the voltage level V0. In response to the input bit INB1 having the logic value “0”, the input bit INB1B has the logic value “1”. In response to the stored bit SBT1 having the logic value “1” and the input bit INB1B having the logic value “1”, the read bit line signal VRBL has the voltage level V2 corresponding to the logic value “1”.

During the period P6A3, the storage node signal VSN has the voltage level VH, corresponding to the stored bit SBT1 having the logic value “1”. The input bit INB1 has the logic value “1”, such that the voltage signal VW1 has the voltage level V2. In response to the input bit INB1 having the logic value “1”, the input bit INB1B has the logic value “0”. In response to the stored bit SBT1 having the logic value “1” and the input bit INB1B having the logic value “0”, the read bit line signal VRBL has the voltage level V0 corresponding to the logic value “0”.

During the period P6A4, the storage node signal VSN has the voltage level VH, corresponding to the stored bit SBT1 having the logic value “1”. The input bit INB1 has the logic value “0”, such that the voltage signal VW1 has the voltage level V0. In response to the input bit INB1 having the logic value “0”, the input bit INB1B has the logic value “1”. In response to the stored bit SBT1 having the logic value “1” and the input bit INB1B having the logic value “1”, the read bit line signal VRBL has the voltage level V2 corresponding to the logic value “1”.

FIG. 6B is a timing diagram of voltage signals in FIG. 3C, illustrated in accordance with some embodiments of the present disclosure. Referring to FIG. 6B, FIG. 3C, and FIG. 1, FIG. 6B illustrates the variations of the voltage signals VW1, the read bit line signal VRBL, and the storage node signal VSN during periods P6B1-P6B4. In some embodiments, FIG. 6B corresponds to the stored bit SBT1 having the logic value “0” in FIG. 3C.

During the period P6B1, the stored bit SBT1 has the logic value “0”, such that the storage node signal VSN has the voltage level VL. The input bit INB1 has the logic value “1”, such that the voltage signal VW1 has the voltage level V2. In response to the input bit INB1 having the logic value “1”, the input bit INB1B has the logic value “0”. In response to the stored bit SBT1 having the logic value “0” and the input bit INB1B having the logic value “0”, the read bit line signal VRBL has the voltage level V2 corresponding to the logic value “1”.

During the period P6B2, the storage node signal VSN has the voltage level VL, corresponding to the stored bit SBT1 having the logic value “0”. The input bit INB1 has the logic value “0”, such that the voltage signal VW1 has the voltage level V0. In response to the input bit INB1 having the logic value “0”, the input bit INB1B has the logic value “1”. In response to the stored bit SBT1 having the logic value “0” and the input bit INB1B having the logic value “1”, the read bit line signal VRBL has the voltage level V0 corresponding to the logic value “0”.

During the period P6B3, the storage node signal VSN has the voltage level VL, corresponding to the stored bit SBT1 having the logic value “0”. The input bit INB1 has the logic value “1”, such that the voltage signal VW1 has the voltage level V2. In response to the input bit INB1 having the logic value “1”, the input bit INB1B has the logic value “0”. In response to the stored bit SBT1 having the logic value “0” and the input bit INB1B having the logic value “0”, the read bit line signal VRBL has the voltage level V1 corresponding to the logic value “1”.

During the period P6B4, the storage node signal VSN has the voltage level VL, corresponding to the stored bit SBT1 having the logic value “0”. The input bit INB1 has the logic value “0”, such that the voltage signal VW1 has the voltage level V0. In response to the input bit INB1 having the logic value “0”, the input bit INB1B has the logic value “1”. In response to the stored bit SBT1 having the logic value “0” and the input bit INB1B having the logic value “1”, the read bit line signal VRBL has the voltage level V0 corresponding to the logic value “0”.

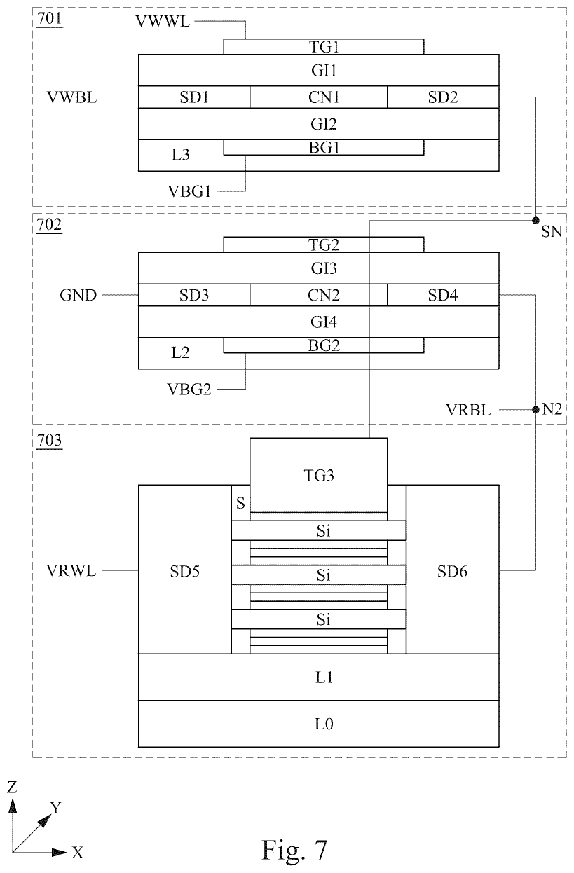

FIG. 7 is a cross section diagram of the memory device 100, illustrated in accordance with some embodiments of the present disclosure. The Y direction points into the paper in FIG. 7.

Referring to FIG. 7 and FIG. 1, the memory device 100 includes portions 701-703. The portion 701 corresponds to the switch DG1. The portion 702 corresponds to the switch DG2. The portion 703 corresponds to the switch S1.

As illustratively shown in FIG. 7, the portion 701 includes a layer L3, isolation structures GI1-GI2, source/drain structures SD1-SD2, a channel structure CN1, and gate structures TG1 and BG1. The layer L3, the gate structure BG1, the isolation structure GI2, the channel structure CN1, the isolation structure GI1, and the gate structure TG1 are arranged in order along a Z direction. The source/drain structure SD1, the channel structure IN1, and the source/drain structure SD2 are arranged in order along an X direction. In some embodiments, the X direction and the Z direction are perpendicular with each other.

In the portion 701, the gate structure BG1 is formed above the layer L3 and the isolation structure GI2 is formed above the gate structure BG1. The channel structure CN1 is formed between the source/drain structure SD1 and SD2. The source/drain structure SD1 and SD2 are isolated from the gate structures TG1 and BG1 by the isolation structures GI1 and GI2 in the Z direction, respectively.

In some embodiments, the gate structure BG1 corresponds to the gate terminal of the switch DG1 in FIG. 1, and is configured to receive the control signal VBG1. The gate structure TG1 corresponds to the control terminal of the switch DG1 in FIG. 1, and is configured to receive the write word line signal VWWL. The source/drain structure SD1 corresponds to a terminal of the switch DG1, and is configured to receive the write bit line signal VWBL. The source/drain structure SD2 corresponds to another terminal of the switch DG1, and is coupled to the portion 702 at the storage node SN.

As illustratively shown in FIG. 7, the portion 702 includes a layer L2, isolation structures GI3-GI4, source/drain structures SD3-SD4, a channel structure CN2, and gate structures TG2 and BG2. The layer L2, the gate structure BG2, the isolation structure GI4, the channel structure CN2, the isolation structure GI3, and the gate structure TG2 are arranged in order along a Z direction. The source/drain structure SD3, the channel structure CN2, and the source/drain structure SD4 are arranged in order along an X direction.

In the portion 702, the gate structure BG2 is formed above the layer L2 and the isolation structure GI4 is formed above the gate structure BG2. The channel structure CN2 is formed between the source/drain structure SD3 and SD4. The source/drain structure SD3 and SD4 are isolated from the gate structures TG2 and BG2 by the isolation structures GI3 and GI4 in the Z direction, respectively.

In some embodiments, the gate structure BG2 corresponds to the gate terminal of the switch DG2 in FIG. 1, and is configured to receive the control signal VBG2. The gate structure TG2 corresponds to the control terminal of the switch DG2 in FIG. 1, and is coupled to the portion 701 at the storage node SN. The gate structure TG2 is further coupled to the gate structure TG3 in the portion 703. The source/drain structure SD3 corresponds to a terminal of the switch DG2, and is configured to receive the reference voltage signal GND. The source/drain structure SD4 corresponds to another terminal of the switch DG2, and is coupled to the portion 703 at the node N2. The source/drain structure SD4 is further configured to output the read bit line signal VRBL.

As illustratively shown in FIG. 7, the portion 703 includes layers L0-L1, a spacer s, source/drain structures SD5-SD6, channel structures CN3-CN5, and a gate structure TG3. The layer L0 and L1 are arranged in order along the Z direction. The channel structures CN3, CN4, and CN5 are arranged in order along the Z direction.

In some embodiments, the source/drain structure SD5 corresponds to a terminal of the switch S1 in FIG. 1, and is configured to receive the read word line signal VW1. The source/drain structure SD6 corresponds to another terminal of the switch S1 in FIG. 1, and is configured to generate the read bit line signal VRBL at the node N2. The gate structure TG3 corresponds to the control terminal of the switch S1, and is coupled to each of the portions 701 and 702. The gate structure TG3 is further configured to receive the storage node signal VSN.

In some embodiments, the layer L0 is implemented by a substrate. The layer L1 is implemented by a channel stop layer. Each of the layers L2 and L3 is implemented by silicon dioxide. Each of the channel structures CN3-CN5 is implemented by silicon. Each of the channel structures CN1-CN5 is implemented by Indium gallium zinc oxide (IGZO).

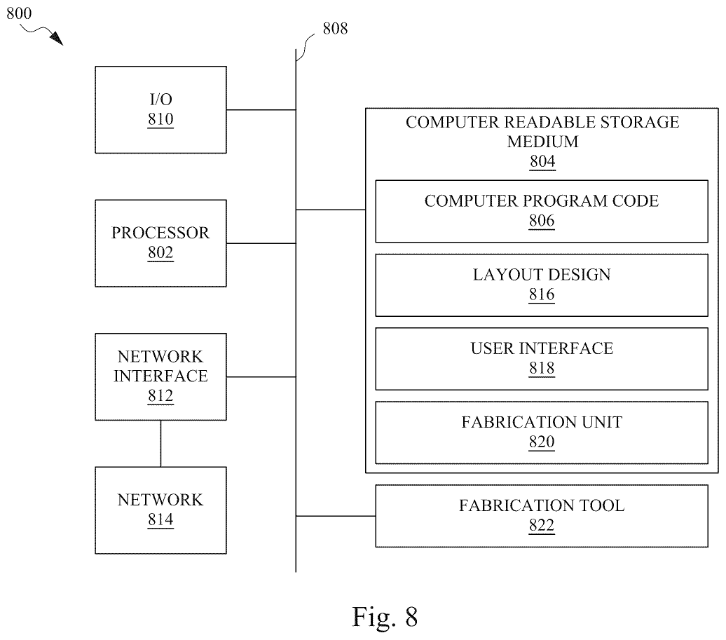

FIG. 8 is a schematic diagram of a system 800 for designing and manufacturing at least one of the memory devices described herein, illustrated in accordance with some embodiments of the present disclosure. The system 800 generates or places one or more IC layout designs corresponding to at least one of the memory devices described herein, as described herein. In some embodiments, the system 800 manufactures one or more memory devices based on the one or more IC layout designs, as described herein. The system 800 includes a hardware processor 802 and a non-transitory, computer readable storage medium 804 encoded with, e.g., storing, the computer program code 806, e.g., a set of executable instructions. The computer readable storage medium 804 is configured for interfacing with manufacturing machines for producing the semiconductor device. The processor 802 is electrically coupled to the computer readable storage medium 804 by a bus 807. The processor 802 is also electrically coupled to an I/O interface 810 by the bus 807. A network interface 812 is also electrically connected to the processor 802 by the bus 807. Network interface 812 is connected to a network 814, so that the processor 702 and the computer readable storage medium 804 are capable of connecting to external elements via network 814. The processor 802 is configured to execute the computer program code 806 encoded in the computer readable storage medium 804 in order to cause the system 800 designing and manufacturing at least one of the memory devices described herein.

In some embodiments, the processor 802 is a central processing unit (CPU), a multi-processor, a distributed processing system, an application specific integrated circuit (ASIC), and/or a suitable processing unit.

In some embodiments, the computer readable storage medium 804 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 804 includes a compact disk-read only memory (CD-ROM), a compact disk-read/write (CD-R/W), and/or a digital video disc (DVD).

In some embodiments, the storage medium 804 also stores information needed for designing and manufacturing at least one of the memory devices described herein, such as layout design 816, user interface 817, fabrication unit 820, and/or a set of executable instructions to designing and manufacturing at least one of the memory devices described herein.

In some embodiments, the storage medium 804 stores instructions (e.g., the computer program code 806) for interfacing with manufacturing machines. The instructions (e.g., the computer program code 806) enable the processor 802 to generate manufacturing instructions readable by the manufacturing machines to effectively implement the memory devices described herein.

The system 800 includes the I/O interface 810. The I/O interface 810 is coupled to external circuitry. In some embodiments, the I/O interface 810 includes a keyboard, keypad, mouse, trackball, trackpad, and/or cursor direction keys for communicating information and commands to the processor 802.

The system 800 also includes the network interface 812 coupled to the processor 802. The network interface 812 allows the system 800 to communicate with the network 814, to which one or more other computer systems are connected. The network interface 812 includes wireless network interfaces such as BLUETOOTH, WIFI, WIMAX, GPRS, or WCDMA; or wired network interface such as ETHERNET, USB, or IEEE-13154. In some embodiments, the designing and manufacturing of at least one of the memory devices described herein is implemented in two or more systems 800, and information such as layout design, user interface and fabrication unit are exchanged between different systems 800 by the network 814.

The system 800 is configured to receive information related to a layout design through the I/O interface 810 or network interface 812. The information is transferred to the processor 802 by the bus 807 to determine a layout design for producing an IC. The layout design is then stored in the computer readable medium 804 as the layout design 816. The system 800 is configured to receive information related to a user interface through the I/O interface 810 or network interface 812. The information is stored in the computer readable medium 804 as the user interface 817. The system 800 is configured to receive information related to a fabrication unit through the I/O interface 810 or network interface 812. The information is stored in the computer readable medium 804 as the fabrication unit 820. In some embodiments, the fabrication unit 820 includes fabrication information utilized by the system 700.

In some embodiments, the designing and manufacturing of at least one of the memory devices described herein is implemented as a standalone software application for execution by a processor. In some embodiments, the designing and manufacturing of at least one of the memory devices described herein is implemented as a software application that is a part of an additional software application. In some embodiments, the designing and manufacturing of at least one of the memory devices described herein is implemented as a plug-in to a software application. In some embodiments, the designing and manufacturing of at least one of the memory devices described herein is implemented as a software application that is a portion of an EDA tool. In some embodiments, the designing and manufacturing of at least one of the memory devices described herein is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the memory devices described herein is implemented by a manufacturing device to manufacture an integrated circuit using a set of masks manufactured based on one or more layout designs generated by the system 800. In some embodiments, the system 800 includes a manufacturing device (e.g., fabrication tool 822) to manufacture an integrated circuit using a set of masks manufactured based on one or more layout designs of the present disclosure.

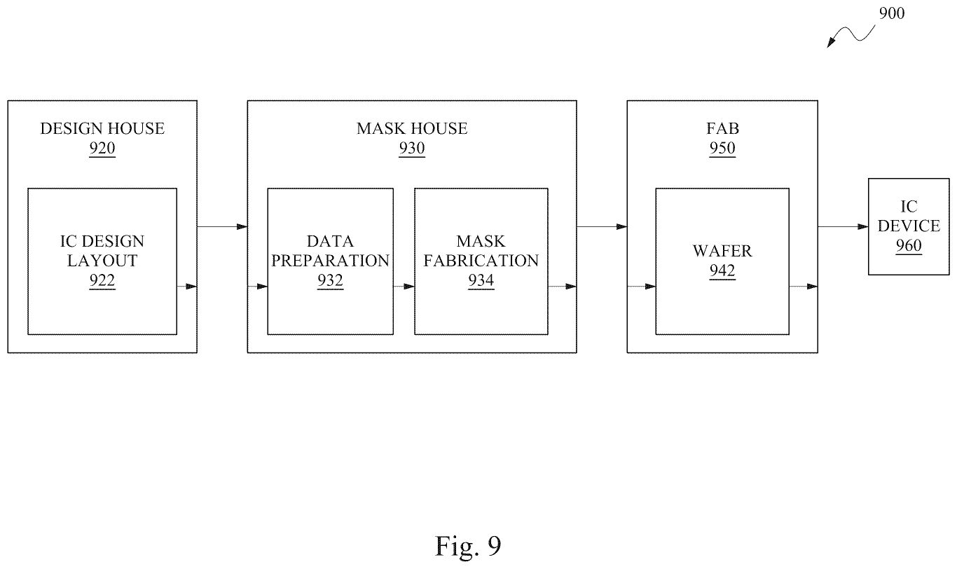

FIG. 9 is a block diagram of an integrated circuit (IC)/semiconductor device manufacturing system 900, and an IC manufacturing flow associated therewith, illustrated in accordance with some embodiments of the present disclosure.

In FIG. 9, the IC manufacturing system 900 includes entities, such as a design house 920, a mask house 930, and an IC manufacturer/fabricator (“fab”) 940, that interact with one another in the design, development, and manufacturing cycles and/or services related to manufacturing an IC device (semiconductor device) 960 including at least one of the memory devices described herein. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 940 is owned by a single company. In some embodiments, two or more of design house 920, mask house 930, and IC fab 940 coexist in a common facility and use common resources.

The design house (or design team) 920 generates an IC design layout 922. The IC design layout 922 includes various geometrical patterns designed for the IC device 960. The geometrical patterns correspond to patterns of metal, oxide, or semiconductor layers that make up the various components of the IC device 960 to be fabricated. The various layers combine to form various IC features. For example, a portion of the IC design layout 922 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 920 implements a proper design procedure to form the IC design layout 922. The design procedure includes one or more of logic design, physical design or place and route. The IC design layout 922 is presented in one or more data files having information of the geometrical patterns. For example, the IC design layout 922 can be expressed in a GDSII file format or DFII file format.

The mask house 930 includes mask data preparation 932 and mask fabrication 934. The mask house 930 uses the IC design layout 922 to manufacture one or more masks to be used for fabricating the various layers of the IC device 960 according to the IC design layout 922. The mask house 930 performs the mask data preparation 932, where the IC design layout 922 is translated into a representative data file (“RDF”). The mask data preparation 932 provides the RDF to the mask fabrication 934. The mask fabrication 934 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 932 to comply with particular characteristics of the mask writer and/or requirements of the IC fab 940. In FIG. 9, the mask data preparation 932 and mask fabrication 934 are illustrated as separate elements. In some embodiments, the mask data preparation 932 and mask fabrication 934 can be collectively referred to as mask data preparation.

In some embodiments, the mask data preparation 932 includes optical proximity correction (OPC) which uses lithography enhancement techniques to compensate for image errors, such as those that can arise from diffraction, interference, other process effects and the like. OPC adjusts the IC design layout 922. In some embodiments, the mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 934, which may undo part of the modifications performed by OPC in order to meet mask creation rules.

In some embodiments, the mask data preparation 932 includes lithography process checking (LPC) that simulates processing that will be implemented by the IC fab 940 to fabricate the IC device 960. LPC simulates this processing based on the IC design layout 922 to create a simulated manufactured device, such as the IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the herein description of the mask data preparation 932 has been simplified for the purposes of clarity. In some embodiments, the mask data preparation 932 includes additional features such as a logic operation (LOP) to modify the IC design layout according to manufacturing rules. Additionally, the processes applied to the IC design layout 922 during the mask data preparation 932 may be executed in a variety of different orders.

After the mask data preparation 932 and during mask fabrication 934, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 940 is an IC fabrication entity that includes one or more manufacturing facilities for the fabrication of a variety of different IC products. In some embodiments, the IC fab 940 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 940 uses the mask (or masks) fabricated by the mask house 930 to fabricate the IC device 960. Thus, the IC fab 940 at least indirectly uses the IC design layout 922 to fabricate the IC device 960. In some embodiments, a semiconductor wafer is fabricated by the IC fab 940 using the mask (or masks) to form the IC device 960. The semiconductor wafer 942 includes a silicon substrate or other proper substrate having material layers formed thereon. Semiconductor wafer further includes one or more of various doped regions, dielectric features, multilevel interconnects, and the like (formed at subsequent manufacturing steps).

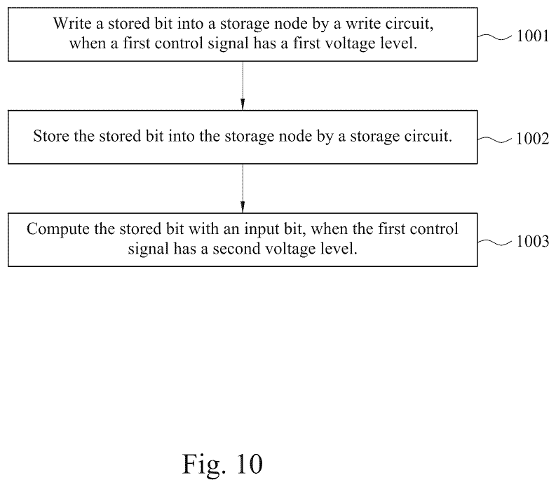

FIG. 10 is a flow diagram of a method 1000 of operating the memory device 100, illustrated in accordance with some embodiments of the disclosure. As shown in FIG. 10, the method 1000 includes operations 1001-1003.

At the operation 1001, write a stored bit into a storage node by a write circuit, when a first control signal has a first voltage level.

For example, the write circuit 101 transmits the write bit line signal VWBL carrying the stored bit SBT1 to the storage node SN, when the control signal VBG2 has the voltage level VN. The memory device 100 performs the operation 1002 after the operation 1001 is performed.

At the operation 1002, store the stored bit into the storage node by a storage circuit.

For example, the storage circuit 102 stores the stored bit SBT1 into the storage node SN. The memory device 100 performs the operation 1003 after the operation 1002 is performed.

At the operation 1003, compute the stored bit with an input bit, when the first control signal has a second voltage level.

For example, when the control signal VBG2 has the voltage level VP, the storage circuit 102 computes the stored bit SBT1 with the input bit INB1. The method 1000 is completed after the operation 1003 is performed.

In some embodiments, the method 1000 further comprises writing the stored bit into the storage node by a write circuit comprises. Writing the stored bit into the storage node by a write circuit comprises receiving a second control signal by the write circuit; shifting a voltage level of the second control signal to the second voltage level; transmitting the stored bit into the storage node; and shifting the voltage level of the second control signal to the second voltage level, when the stored bit is stored into the storage node.

For example, the write circuit 101 writes the stored bit SBT1 into the storage node SN. Specifically, the write circuit 101 receives the control signal VBG1, and shifts the voltage level of the control signal VBG1 to the voltage level VP. The write circuit 102 transmits the stored bit SBT1 into the storage node SN. Then, the write circuit 102 shifts the voltage level of the control signal VBG1 to the voltage level VN, when the stored bit SBT1 is stored into the storage node SN.

In some embodiments, when the first control signal has the second voltage level, receive the input bit by the storage circuit, and control each of a first switch and a second switch in the storage circuit according to a voltage level of the storage node. Wherein the first switch is turned on, when the stored bit has a first logic value, and the second switch is turned on, when the stored bit has a second logic value.

For example, when the control signal VBG2 has the voltage level VP, the storage circuit 102 receives the input bit INB1 and controls each of the switches S1 and DG2 according to a voltage level of the storage node SN. When the stored bit SBT1 has the logic value “0”, the switch S1 is turned on. When the stored bit SBT1 has the logic value “1”, the switch DG2 is turned on.

In some embodiments, the method 1000 further comprises preforming a first logic operation to the input bit and the stored bit. Preforming a first logic operation to the input bit and the stored bit comprises: receive a first voltage signal carrying the input bit by the first switch, and generates an output signal carrying an output bit according to the input bit and the stored bit. Wherein when at least one of the stored bit and the input bit has the second logic value, the output bit has the second logic value, and when each of the stored bit and the input bit has the first logic value, the output bit has the first logic value.

For example, the storage circuit 102 performs the OR operation to the input bit INB1 and the stored bit SBT1. Specifically, the switch S1 receives the voltage signal VW1 carrying the input bit INB1, and generates the read bit line signal VRBL carrying the output bit OUTB1 according to the input bit INB1 and the stored bit SBT1. Wherein when at least one of the stored bit SBT1 and the input bit INB1 has the logic value “1”, the output bit OUTB1 has the logic value “1”. When each of the stored bit SBT1 and the input bit INB1 has the logic value “0”, the output bit has the logic value “0”.

In some embodiments, the method 1000 further comprises preforming a second logic operation to the input bit and the stored bit. Preforming a second logic operation to the input bit and the stored bit comprises: receive the first voltage signal carrying the input bit by the second switch, and generate the output signal carrying the output bit according to the input bit and the stored bit. Wherein when at least one of the stored bit and the input bit has the first logic value, the output bit has the first logic value, and when each of the stored bit and the input bit has the second logic value, the output bit has the second logic value.

For example, the storage circuit 102 performs the AND operation to the input bit INB1 and the stored bit SBT1. Specifically, the switch DG2 receives the voltage signal VW1 carrying the input bit INB1, and generates the read bit line signal VRBL carrying the output bit OUTB1 according to the input bit INB1 and the stored bit SBT1. Wherein when at least one of the stored bit SBT1 and the input bit INB1 has the logic value “0”, the output bit OUTB1 has the logic value “0”. When each of the stored bit SBT1 and the input bit INB1 has the logic value “1”, the output bit has the logic value “1”.

In some embodiments, the method 1000 further comprises preforming a third logic operation to the input bit and the stored bit. Preforming a third logic operation to the input bit and the stored bit comprises: receive the first voltage signal carrying the input bit by the second switch, receive a second voltage signal carrying another input bit being complementary to the input bit by the second switch, and generate the output signal carrying the output bit according to the input bit and the stored bit. Wherein when the input bit has a logic value being different from the stored bit, the output bit has the second logic value, and when the input bit has a logic value being same as the stored bit, the output bit has the first logic value.

For example, the storage circuit 102 performs the XOR operation to the input bit INB1 and the stored bit SBT1. Specifically, the switch S1 receives the voltage signal VW1 carrying the input bit INB1, the switch DG2 receives the voltage signal VW1 carrying the input bit INB1B, and generates the read bit line signal VRBL carrying the output bit OUTB1 according to the input bit INB1 and the stored bit SBT1. Wherein when the input bit INB1 has a logic value being different from the stored bit SBT1, the output bit OUTB1 has the logic value “1”. When the input bit INB1 has a logic value being same as the stored bit SBT1, the output bit OUTB1 has the logic value “0”.

Also disclosed is a memory device. The memory device comprises a write circuit configured to write a stored bit into a storage node, when a first control signal has a first voltage level; and a storage circuit configured to store the stored bit at the storage node and receive the first control signal, wherein when the first control signal has a second voltage level, the storage circuit computes the stored bit with a first input bit to generate an output bit, and the second voltage level is higher than the first voltage level.

Also disclosed is a memory device. The memory device comprises a first switch; a second switch, a control terminal of the second switch coupled to a first terminal of the first switch at a storage node; and a third switch, a control terminal of the third switch coupled the storage node, wherein a first terminal of the second switch is coupled to a first terminal of the third switch, when the storage node has a first voltage level, the third switch is turned on and the second switch is turned off, and when the storage node has a second voltage level, the second switch is turned on and the third switch is turned off.

Also disclosed is a method. The method comprises writing a stored bit into a storage node by a write circuit, when a first control signal has a first voltage level; storing the stored bit into the storage node by a storage circuit; and computing the stored bit with an input bit, when the first control signal has a second voltage level, wherein the first voltage level is different from the second voltage level.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a write circuit configured to write a stored bit into a storage node, when a first control signal has a first voltage level ; and
a storage circuit configured to store the stored bit at the storage node and receive the first control signal,
wherein when the first control signal has a second voltage level, the storage circuit computes the stored bit with a first input bit to generate an output bit, and
the second voltage level is higher than the first voltage level.

2. The memory device of claim 1, wherein the storage circuit further comprises:
a first switch, a gate terminal of the first switch configured to receive the first control signal, and
a second switch, a control terminal of the second switch coupled to a control terminal of the first switch at the storage node.

3. The memory device of claim 2, wherein
a third switch coupled to each of the first switch and the second switch at the storage node,
the third switch is configured to receive a second control signal and transmit the stored bit into the storage node,
when the second control signal has the second voltage level, the third switch transmits the stored bit into the storage node, and
after the stored bit is stored into the storage node by the storage circuit, the second control signal has the first voltage level.

4. The memory device of claim 1, wherein the storage circuit further comprises:
a first switch configured to receive the first control signal and a first voltage signal; and
a second switch configured to receive a second voltage signal,
wherein when the storage circuit preforms a first logic operation to the first input bit and the stored bit, the second voltage signal carries the first input bit, and
when the storage circuit preforms a second logic operation to the first input bit and the stored bit, the first voltage signal carries the first input bit.

5. The memory device of claim 4, wherein
when the first logic operation is performed, and at least one of the stored bit and the input bit has a first logic value, the output bit has the first logic value, and
when the first logic operation is performed, and each of the stored bit and the input bit has a second logic value, the output bit has the second logic value.

6. The memory device of claim 5, wherein
when the second logic operation is performed, and at least one of the stored bit and the input bit has the second logic value, the output bit has the second logic value, and
when the second logic operation is performed, and each of the stored bit and the input bit has the first logic value, the output bit has the first logic value.

7. The memory device of claim 6, wherein when the storage circuit preforms a third logic operation to the input bit and the stored bit, the second voltage signal carries the input bit and the first voltage signal carries a second input bit which is complementary to the first input bit.

8. The memory device of claim 7, wherein
when the third logic operation is performed, and the input bit has a logic value being different from the stored bit, the output bit has the first logic value, and
when the third logic operation is performed, and the input bit has a logic value being same as the stored bit, the output bit has the second logic value.

9. A memory device, comprising:
a first switch;
a second switch, a control terminal of the second switch coupled to a first terminal of the first switch at a storage node; and
a third switch, a control terminal of the third switch coupled the storage node,
wherein a first terminal of the second switch is coupled to a first terminal of the third switch,
when the storage node has a first voltage level, the third switch is turned on and the second switch is turned off, and
when the storage node has a second voltage level, the second switch is turned on and the third switch is turned off.

10. The memory device of claim 9, wherein
the first switch is configured to transmit a write word line signal to the storage node, when a first control signal has a third voltage level,
the first control signal is adjusted from the third voltage level to a fourth voltage level, after the stored bit is stored into the storage node, and
the third voltage level is higher than the fourth voltage level.

11. The memory device of claim 10, wherein
the second switch is configured to receive a second control signal,
when the second control signal has the third voltage level, each of the second switch and the third switch computes the stored bit with an input bit to generate an output bit at a first node, and
wherein the first terminal of the second switch is coupled to the first terminal of the third switch at the first node.

12. The memory device of claim 11, wherein
when each of the second switch and the third switch performs a first logic computation, the third switch receives a first voltage signal carrying the input bit, and the second switch receives a second voltage signal carrying another input bit which is complementary to the input bit,
when a logic value of the input bit is different from a logic value of the stored bit, the output bit has a first logic value, and
when the logic value of the input bit is same as the logic value of the stored bit, the output bit has a second logic value.

13. The memory device of claim 12, wherein
when each of the second switch and the third switch performs a second logic computation, the first voltage signal has a ground voltage level, and the second voltage signal carries the input bit,
when at least one of the stored bit and the input bit has the second logic value, the output bit has the second logic value, and
when each of the stored bit and the input bit has the first logic value, the output bit has the first logic value.

14. The memory device of claim 10, wherein
when the first control signal has the first voltage level, a threshold voltage of the first switch is decreased from a first level to a second level,
when the first control signal has the second voltage level, the threshold voltage of the first switch is increased from the second level to the first level, and
the first level is higher than the second level.

15. A method, comprising:
writing a stored bit into a storage node by a write circuit, when a first control signal has a first voltage level;
storing the stored bit into the storage node by a storage circuit; and
computing the stored bit with an input bit, when the first control signal has a second voltage level,
wherein the first voltage level is different from the second voltage level.

16. The method of claim 15, wherein writing the stored bit into the storage node by a write circuit comprises:
receiving a second control signal by the write circuit;
shifting a voltage level of the second control signal to the second voltage level;
transmitting the stored bit into the storage node; and
shifting the voltage level of the second control signal to the first voltage level, when the stored bit is stored into the storage node.

17. The method of claim 15, wherein computing the stored bit with the input bit further comprising:
when the first control signal has the second voltage level, receiving the input bit by the storage circuit; and
controlling each of a first switch and a second switch in the storage circuit according to a voltage level of the storage node,
wherein the first switch is turned on, when the stored bit has a first logic value, and
the second switch is turned on, when the stored bit has a second logic value.

18. The method of claim 17, wherein computing the stored bit with the input bit further comprising:
preforming a first logic operation to the input bit and the stored bit, comprising:
receiving a first voltage signal carrying the input bit by the first switch; and
generating an output signal carrying an output bit according to the input bit and the stored bit,
wherein when at least one of the stored bit and the input bit has the second logic value, the output bit has the second logic value, and
when each of the stored bit and the input bit has the first logic value, the output bit has the first logic value.

19. The method of claim 18, further comprising:
preforming a second logic operation to the input bit and the stored bit, comprising:
receiving the first voltage signal carrying the input bit by the second switch; and
generating the output signal carrying the output bit according to the input bit and the stored bit,
wherein when at least one of the stored bit and the input bit has the first logic value, the output bit has the first logic value, and
when each of the stored bit and the input bit has the second logic value, the output bit has the second logic value.

20. The method of claim 19, further comprising:
preforming a third logic operation to the input bit and the stored bit, comprising:
receiving the first voltage signal carrying the input bit by the second switch;
receiving a second voltage signal carrying another input bit which is complementary to the input bit by the second switch; and
generating the output signal carrying the output bit according to the input bit and the stored bit,
wherein when a logic value of the input bit is different from a logic value of the stored bit, the output bit has the second logic value, and
when the logic value of the input bit is same as the logic value of the stored bit, the output bit has the first logic value.
